(19) United States
(12) Patent Application Publication
(10) Pub. No.: US 2026/0200176 A1
(43) Pub. Date: Jul. 16, 2026

(54) DYNAMIC STRENGTHENING USING 3D PRINTING AND ROBOTIC SUPPORT

(71) Applicant: INTERNATIONAL BUSINESS MACHINES CORPORATION, Armonk, NY (US)

(72) Inventors: Jeremy R. Fox, Georgetown, TX (US); Martin G. Keen, Cary, NC (US); Sarbajit Kumar Rakshit, Kolkata (IN); Carolina Garcia Delgado, Zapopan (MX)

(21) Appl. No.: 19/020,392

(22) Filed: Jan. 14, 2025

(51) Int. Cl. B29C 64/393; B33Y 10/00; B33Y 50/02; G06F 30/27

(52) U.S. Cl. CPC B29C 64/393; G06F 30/27; B33Y 10/00; B33Y 50/02

(57) ABSTRACT

A computer-implemented method includes analyzing collected data relating to physical attributes of a structure and load distribution patterns and simulating loading scenarios on the structure based on one or more structural analysis tools. Weak points and failure points are identified based on the simulation. Modifications are computed to the structure based on the weak points and failure points. A digital model of the modifications to the structure is generated. Three-dimensional (3D) printing the modifications to the structure is performed by adding material to the weak points and failure points on the structure utilizing a layer-by-layer deposition process.

### BACKGROUND

The present invention generally relates to structural modification and strengthening systems and methods, and more particularly to dynamic structural modification and strengthening systems and methods using three-dimensional (3D) printing technology and swarm robotics for real-time analysis and reinforcement of structures.

Structural integrity in the design and maintenance of buildings, bridges, and other infrastructure needs to be maintained. As structures age or face changing environmental conditions, their ability to withstand various loads and stresses can diminish. This degradation can lead to safety concerns, reduced functionality, and increased maintenance costs.

Traditional methods of structural reinforcement often involve extensive manual labor, time-consuming processes, and significant disruption to the structure's use. These methods typically require the construction and replacement application of additional materials, such as steel plates or fiber-reinforced polymers, which can be costly and may alter the aesthetic or functional characteristics of the structure.

### SUMMARY

In accordance with an embodiment of the present invention, a computer-implemented method includes analyzing collected data relating to physical attributes of a structure and load distribution patterns and simulating loading scenarios on the structure based on one or more structural analysis tools. Weak points and failure points are identified based on the simulation. Modifications are computed to the structure based on the weak points and failure points. A digital model of the modifications to the structure is generated. Three-dimensional (3D) printing the modifications to the structure is performed by adding material to the weak points and failure points on the structure utilizing a layer-by-layer deposition process.

In accordance with another embodiment of the present invention, a computer system includes a processor set, one or more computer-readable storage media and program instructions stored on the one or more computer-readable storage media to cause the processor set to perform operations. The operations include analyzing collected data relating to physical attributes of a structure and load distribution patterns; simulating loading scenarios on the structure based on one or more structural analysis tools; identifying weak points and failure points based on the simulation; computing modifications to the structure based on the weak points and failure points; generating a digital model of the modifications to the structure; and three-dimensional (3D) printing the modifications to the structure by adding material to the weak points and failure points on the structure utilizing a layer-by-layer deposition process.

In accordance with another embodiment of the present invention, a computer program product includes one or more computer-readable storage media and program instructions stored on the one or more computer-readable storage media to perform operations. The operations include analyzing collected data relating to physical attributes of a structure and load distribution patterns; simulating loading scenarios on the structure based on one or more structural analysis tools; identifying weak points and failure points based on the simulation; computing modifications to the structure based on the weak points and failure points; generating a digital model of the modifications to the structure; and controlling three-dimensional (3D) printing the modifications to the structure by adding material to the weak points and failure points on the structure utilizing a layer-by-layer deposition process.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 is a block diagram of a system for dynamic strengthening using 3D printing and robotic support, in accordance with an embodiment of the present invention;

FIG. 2 shows a cross-sectional and side view for a structure before and after additive manufacturing to modify or repair the structure, in accordance with an embodiment of the present invention;

FIG. 3 shows a side view for a structure during additive manufacturing using a swarm of printing robots, in accordance with an embodiment of the present invention;

FIG. 4 is a block diagram showing a computer environment for dynamic strengthening using 3D printing and robotic support, in accordance with an embodiment of the present invention; and

FIG. 5 is a flow diagram showing methods for dynamic strengthening using 3D printing and robotic support, in accordance with an embodiment of the present invention.

### DETAILED DESCRIPTION

In accordance with embodiments of the present invention, systems and methods are described for dynamic structural modification and strengthening systems and methods that integrate 3D printing technology, swarm robotics, and real-time analysis to enhance the integrity of structures. The systems and methods provide structural reinforcement by providing a more efficient, accurate, and less disruptive approach.

The systems and methods can incorporate a computational analysis component that simulates various load scenarios and identifies potential weak points in a structure. Based on this analysis, an optimal design modification can be proposed to improve the structure's cross-sectional moment of inertia, enhancing its resistance to bending and torsional stresses. An adaptive manufacturing method may be employed, utilizing 3D printing technology to apply additional material precisely where needed. This approach can permit customized reinforcement that adapts to the specific requirements of each structure. The systems can also include a network of robotic units that work collaboratively to implement the modifications. These robots may be capable of navigating the structure, applying 3D printed materials, and potentially performing other tasks related to structural reinforcement.

In accordance with embodiments of the present invention, real-time structural health monitoring, advanced simulation techniques, and automated manufacturing processes are combined to offer a more responsive and efficient solution for maintaining and improving the integrity of buildings, bridges, and other infrastructure. The dynamic nature of the system permits ongoing assessment and adaptation to changing structural needs over time.

In an embodiment, dynamic structural modification and strengthening using 3D printing includes analyzing collected data relating to existing physical attributes of a structure and load distribution patterns. Loading scenarios are simulated on the structure based on one or more machine learning techniques and finite element analysis. Weak points and failure points are identified based on the simulation. Modifications to the structure are computed based on the weak points and failure points. Material is added to the weak points and failure points on the structure by utilizing a layer-by-layer deposition process.

In an embodiment, the material added to the weak points and failure points can be provided by deploying robotic units to collaboratively add the material to the weak points and failure points. The material can also be added to redistribute any increased load resulting from the added materials. The robotic units can record an outcome of the modifications, wherein the recordings are fed back to the system for continuous learning.

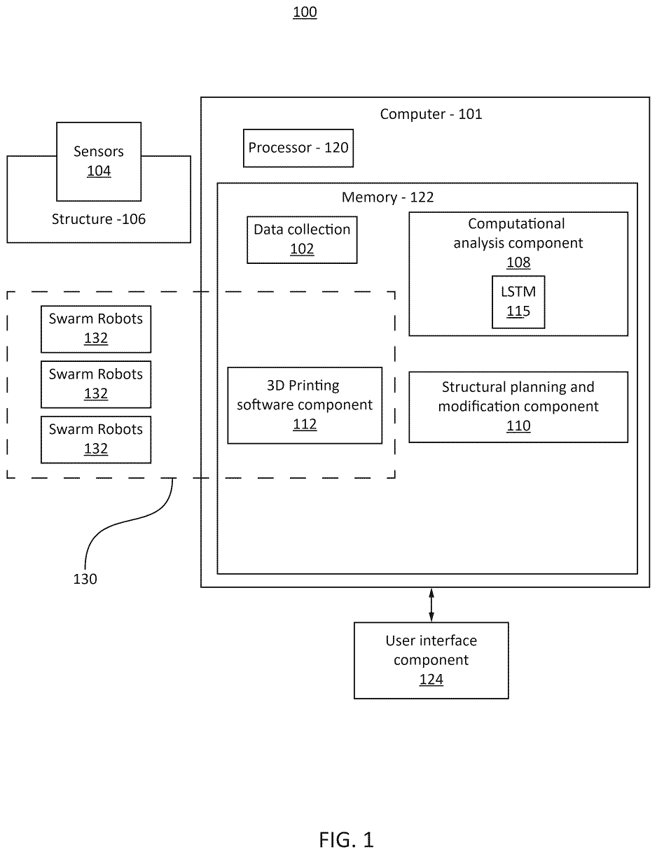

Referring now to the drawings in which like numerals represent the same or similar elements and initially to FIG. 1, a system 100 for dynamic strengthening using 3D printing and robotic support is shown and described in accordance with embodiments of the present invention. The system 100 can include computer 101, which can include a processor 120 and memory 122. A data collection component 102 can be included to gather information about a structure's current physical state, load distribution patterns, and environmental conditions. The data collection component 102 can be included in hardware and/or software. The data collection can be performed by, e.g., sensors 104. The sensors 104 can include strain gauges, hardness tester, optical inspection tools, ultrasonic inspection tools, embedded internet or Things (IoT) sensors or any other sensors or measuring device either on or in a structure 106. The sensors 104 may continuously monitor various parameters such as stress, strain, temperature, humidity, etc.

A computational analysis component 108 can process collected data to simulate various load scenarios and identify potential weak points in the structure 106. The computational analysis component 108 can employ machine learning techniques, finite element analysis and other analysis tools to predict structural behavior of the structure 106 under different conditions.

The system 100 may also include a structural modification planning component 110. The structural modification planning component 110 may use the results from the computational analysis to provide optimal or candidate design modifications. These modifications may be aimed at improving the structure's cross-sectional moment of inertia and enhancing its resistance to bending and torsional stresses. While adding materials may provide for added structural support, the design modification can consider the longevity of the modification as well as operational, environmental or other constraints to provide an optimal solution. For example, a bending repair on a bridge or causeway can include adding material to resist bending. The added material could be added in an asymmetrical fashion and include a protective layer to provide corrosion protection.

A 3D printing software component 112 can be incorporated to compute the additive materials needed to strengthen the identified weak points. The 3D printing software component 112 can determine the amount and type of material to be added, as well as the optimal printing patterns to achieve the desired structural reinforcement. The system 100 includes the processor 120 and memory 122 for executing the various software components and storing relevant data. The processor 120 can coordinate operations of different components and perform calculations, e.g., moments of inertia, bending stress, etc.

To facilitate communication between components, the system 100 can employ predefined communication protocols and application programming interfaces (APIs). These protocols and APIs may enable seamless data exchange and coordination among the various components, ensuring efficient operation of the system 100.

In some cases, the system 100 can include a user interface component 124 for displaying analysis results, proposed modifications, and system status to operators or engineers. The user interface component 124 can permit oversight and intervention in the structural modification process, if needed.

The computational analysis component 108 can compute structural parameters, with a particular focus on moments of inertia. The computational analysis component 108 analyzes the structure's current state and proposes optimal modifications. The computational analysis component 108 can make computations based on geometric measurements of the structure. These can be manual measurement, sensor measurement or measurements made using ultrasound or other radiation penetrating techniques (e.g., X-ray, etc.).

Post-simulation, the system 100 can employ genetic algorithms to generate and test various cross-sectional modification proposals. Here, the cross-sectional changes are symbolically represented as genes within a population. Iteratively proceeding through cycles of selection, crossover, and mutation, the algorithm evolves an optimized design solution to improve the moment of inertia and thereby the overall structural strength.

In some cases, a Finite Element Analysis (FEA) analysis can be performed by the computational analysis component 108 for preliminary analysis of the structure. The computational analysis component 108 can divide the structure into smaller elements and analyze how these elements interact under various load conditions. The computational analysis component 108 can provide valuable insights into stress distribution, displacement, and other structural behaviors, which may be needed for identifying potential weak points.

The computational analysis component 108 can include a load simulation and prediction analysis, which can utilize Long Short-Term Memory Networks (LSTM) 115, a type of Recurrent Neural Network (RNN). The computational analysis component 108 can simulate various load patterns and predict potential weak points in the structure. The LSTM 115 or other neural network may be trained on historical structural load and performance data, allowing it to make accurate predictions about future structural behavior under different load scenarios.

Based on the computational results, the structural modification planning component 110 can generate and test various cross-sectional modification proposals. The structural modification planning component 110 can represent cross-sectional changes and iteratively evolve optimized design solutions. The structural modification planning component 110 may proceed through cycles or iterations to improve the moment of inertia and overall structural strength. The modification proposals can include adding material in a cross-section to determine a response. The cross-section can be modified randomly or in accordance with a physics-informed model. This results in a digital model of an optimized modification proposal which can be employed to guide 3D printing of the repair or modification.

The computational analysis component 108 can include different types of computations and analysis tools that can work in conjunction to provide comprehensive analysis and optimization of the structure's parameters. For example, a FEA component can be included to provide initial insights, the LSTM component can include predictions of future behavior of a current configuration or as a result of potential modifications, etc. The structural modification planning component 110 can propose optimal modifications. Together, the system 100 can dynamically identify weak points and propose effective strengthening solutions.

The system 100 can perform an initial analysis using FEA to understand an existing state and establish a standard performance profile for the structure 106. With pre-established performance metrics, such as stress distribution or displacement under given loads, a quantifiable measure of the structure's current stage of integrity can be obtained.

The processor 120 can include a central processing unit (CPU), a graphics processing unit (GPU) or a microprocessor capable of executing complex algorithms and managing multiple tasks simultaneously. The memory 122 can include both volatile and non-volatile memory. Volatile memory, such as random-access memory (RAM), may be used for temporary storage of data and intermediate results during computations. Non-volatile memory, such as solid-state drives (SSDs) or hard disk drives (HDDs), may store the system's software components, historical data, and long-term records of structural analyses and modifications.

In some cases, the processor 120 and memory 122 can work together to execute software of the system 100. For example, the processor 120 may load the finite element analysis component from the non-volatile memory into the RAM for faster execution. The results of the analysis may then be temporarily stored in RAM before being processed by other components or saved to non-volatile memory for future reference.

The processor 120 and memory 122 can also facilitate the consideration of environmental parameters such as temperature and humidity in the structural analysis. The processor 120 can retrieve sensor data, e.g., temperature and humidity, from the data collection component 102 (e.g., sensors 104), store this data in memory, and incorporate it into the computational models used for structural analysis. This integration of environmental data may allow for more accurate predictions of structural behavior under various conditions.

The memory 122 component can store historical data on environmental conditions and their effects on the structure. This historical data may be used by the processor 120 to identify patterns or trends in structural integrity over time.

The 3D printing software component 112 computes the additive materials needed to enhance the structural integrity of various constructions. By integrating with other system components, the 3D printing software component 112 provides a digital model for printing in accordance with the analysis for structural enhancements. The 3D printing software component 112 can select specific materials for use based on the unique requirements of the structure being reinforced. For example, concrete may be chosen for large, static structures due to its robustness and durability, while polymers or metal alloys might be selected for smaller, dynamic structures where flexibility and strength are needed. The selection process is guided by the input from the computational analysis component 108, which can provide detailed information about the structural weaknesses and the type of reinforcement needed.

The 3D printing software component 112 employs various 3D printing processes tailored to the selected materials. For metal components, powder bed fusion can be utilized, which involves spreading a layer of metal powder and selectively melting it with a laser or electron beam to build the part layer by layer. For polymers, fused deposition modeling could be used, where a thermoplastic filament is extruded through a heated nozzle, layer by layer, to form the part. These processes are chosen based on their ability to meet the specific structural and material requirements identified during the analysis phase.

Furthermore, the 3D printing software component 112 employs Computer-Aided Design (CAD) software to interpret the input data from the structural analysis and generate a precise printing design. This design specifies the exact locations and amounts of material to be added to the structure, ensuring that the modifications are both accurate and effective. The CAD software can translate the modification plans into practical, executable printing instructions that 3D printers can follow.

The dynamic structural modification and strengthening system 100 integrates components to enhance a structure's integrity starting with structural load simulation, which analyzes the structure's current state and identifies potential weak points. This utilizes data from embedded sensors 104 and environmental monitoring systems to create a comprehensive model of the structure's behavior under different load conditions. Once weak points are identified, the computational analysis component 108 generates modification proposals designed to strengthen these areas. These proposals may involve altering the cross-sectional moment of inertia of specific structural elements to improve their resistance to bending and torsional stresses.

The 3D printing software component 112 then receives these modification proposals and translates them into a printable design by selecting appropriate materials and printing techniques based on the specific requirements of each modification.

3D printing can be carried out in a number of ways. In one example, a swarm robotic system 130 works in tandem with the 3D printing software component 112 to implement the proposed modifications. Swarm robots 132 can navigate the structure, establish necessary supports for the printing process, and assist in material deposition. The swarm robotic system 130 can also monitor the printing process in real-time, making adjustments as needed to ensure optimal material placement and load distribution.

Throughout the modification process, the system 100 can continuously monitor the structure's response to the changes being made. This feedback loop permits real-time adjustments to the printing strategy, if necessary, ensuring that the modifications achieve the desired strengthening effect without compromising other aspects of the structure's integrity.

In some embodiments, after the 3D printing process is complete, post-processing steps may be performed to finalize the structural modifications. These steps may include support removal, where temporary structures used during the printing process are carefully detached from the main structure. Surface finishing techniques may also be applied to ensure that the newly added material integrates seamlessly with the existing structure, both functionally and aesthetically. Additionally, thermal treatments may be conducted in some cases to enhance the material properties of the printed additions, such as improving strength or reducing internal stresses.

A final assessment of the modified structure can be performed, which includes comparing the structure's new performance characteristics with the initial analysis and verifying that the intended improvements have been achieved. This can include physical testing or inspections (e.g., visual, ultrasound, X-ray, etc.). The results of this assessment may then be fed back into the system's database, contributing to its ongoing learning process and informing future modification strategies. The system 100 provides structural modification and strengthening that allows for dynamic, targeted improvements that can adapt to the changing needs of structures over time, potentially extending their lifespan and enhancing their performance under various load conditions.

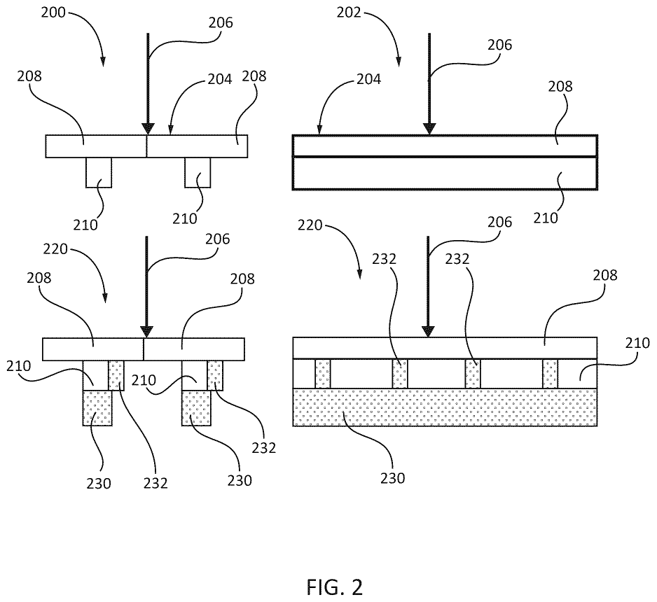

Referring to FIG. 2, a cross-sectional view 200 and a side view 202 are shown for an exemplary structure 204 to be analyzed in accordance with embodiments of the present invention. The structure 204 includes a load 206 centrally applied thereon. The structure 204 can be analyzed using strain gauges, dimensions, materials, etc. These parameters can be measured directly or may be known from specifications or other methods. A moment of inertia is a key parameter in calculating flexural strength of a structural element, such as a beam or column. When the load 206 is applied to the structure 204 (e.g., a beam), top fibers of the structure 204 are compressed while bottom fibers are stretched. The further the material is from a neutral axis (the axis where there is no stress), the greater the stress experienced. A larger moment of inertia means that more of the material is distributed farther from the neutral axis. This effectively increases the section's ability to resist bending, making it stronger against bending stresses. For components subjected to torsional loads (e.g., twisting), such as shafts or certain types of columns, a larger moment of inertia contributes to greater torsional rigidity. This means the component can resist torsional deformation more effectively, which is an important aspect in maintaining structural integrity under twisting forces.

A larger moment of inertia also reduces the deflection or sag in a beam or component under a given load. This reduction in deflection is an important aspect for maintaining the functionality and safety of structures, especially in applications where minimal deflection is critical. In columns, an increased moment of inertia improves the resistance to buckling. Buckling is the sudden, unstable deformation or failure of a structural element under compression. By increasing the moment of inertia, the column becomes less prone to buckling under a given load.

Designing with larger moments of inertia permits engineers to use less material while achieving the desired strength and stiffness. This can lead to more cost-effective and efficient structural designs. Added stress/strain due to additive manufacturing processes (adding to cross sectional area) also needs to be considered in the optimization of the repair.

The T-shaped cross-section of the structure 204 has flanges 208. The flanges 208 and a bottom section 210 increase a cross-sectional moment of inertia of the structure 204. The greater the moment of inertia, the more resistant the structure is to bending. When the load 206 is applied, the T-shaped structure bends or deforms. As a result, this structure may be more prone to bending than is desired.

In the field of structural engineering and construction, strengthening a structure to withstand a change in load patterns, which could result from shifting external forces, modifications, or aging, is a persistent issue. This problem is compounded by the inability to effectively modify structural components to increase their load-bearing capacity and reduce their vulnerability to deformation. Traditional methods often involve complex renovations or even complete replacements, which are time-consuming, expensive, and disruptive. Moreover, these methods do not always guarantee optimal results particularly in terms of enhancing the cross-sectional moment of inertia, one important parameter for bolstering flexural strength and torsional resistance against bending and twisting effects.

In accordance with embodiments of the present invention, dynamic systems and methods are provided to reassess and enhance the structural integrity and load-bearing capability of various structural components within an existing structure. Drawing on simulations for analyzing loads and their respective impacts, the present system identifies structural weak points that need reinforcement. Once identified, the system employs 3D printing technology and a swarm robotic system to add layers of suitable material to those targeted areas, thereby modifying their cross-sectional moment of inertia.

The structure 204 is improved by 3D printed enhancements (e.g., a feature 230 and ribs 232), including to moment of inertia, to form structure 220. Structure 220 has been additively enhanced by 3D printed materials to increase resistance to bending and torsional loads, thereby boosting the structure's overall strength and performance. Other enhancements such as, e.g., additional ribs, fillets, flanges, patches or other features, can also be added.

In an embodiment, load simulation can be performed to determine the type of repair that can be made. Different cross-sectional configurations can be tested digitally before 3D printing, e.g., a swarm robotic system, addresses the structure to provide additive features to address the load or loads. 3D printing technology employed by the swarm robots dynamically identifies and rectifies areas within a structure that needs reinforcement. By continually evaluating the changing load patterns and adjusting the cross-sectional moment of inertia as needed, the system 100 (FIG. 1) can strengthen the structure 220 while reducing deflection and making the structure 220 less prone to bending, buckling, etc.

Unlike standard practices requiring exhaustive reconstruction, the embodiments of the present invention offer in-situ improvement to structural integrity and can continually respond to structure-altering factors, such as, e.g., aging and wear. The system 100 can dynamically identify and strengthen weak sections in the structure 204 to improve its resilience to, e.g., bending and torsional stresses. The system 100 utilizes simulations to predict structural weak points and propose optimal modifications to the structure's cross-sectional moment of inertia. The system 100 generates a modification model that can be used to 3D print on the structure 204. Swarm robots or other 3D printing devices can be guided by the simulations and the proposed modifications to alter the structure 204 to add material to provide the structure 220, which illustratively includes the feature 230 that extends a base of the T-shape and ribs 232 which reduces shear stress. Structural modifications can be implemented using any 3D printing technology that can precisely add material where needed.

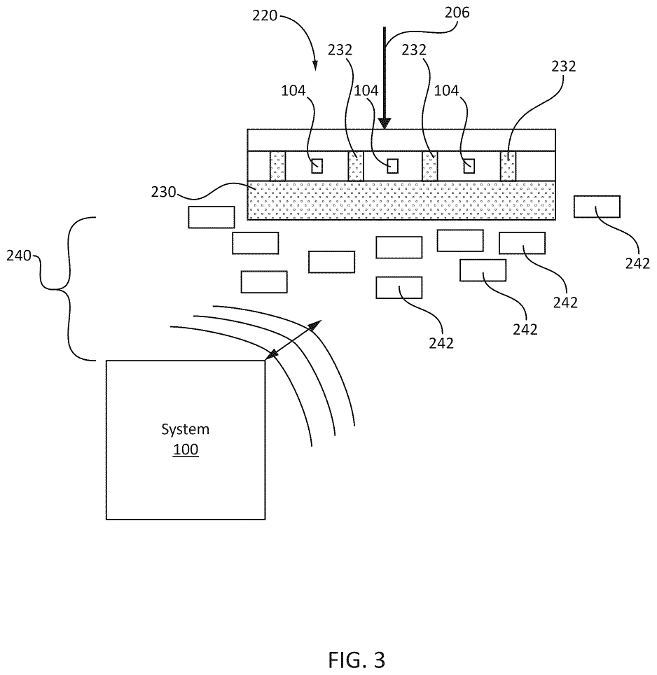

Referring to FIG. 3, in an embodiment, a cooperative robotic network 240 of swarm robots 242 can be employed to assist in the 3D printing process, maintain structural balance during material addition, and record outcomes for continuous system improvement. The structure 220 can include sensors 104 for feedback to the system 100, the swarm robots 242 and/or the cooperative robotic network 240. The feedback can include current physical attributes and load distribution patterns of the structure sourced through embedded or surface sensors 104. The sensors 104 can include IoT or other sensors that can communicate with the cooperative robotic network 240. Environmental conditions like temperature, humidity, and potential dynamic forces such as wind can be accounted for in the dynamic process. Properties of the 3D printing material can be selected in advance or selected in-situ to be used for structural modifications considering the strengthening requirements.

The system 100 can predict potential structural weak points that could compromise the integrity of structure 220 under various load scenarios. Optimal design modifications to the structure's cross-sectional moment of inertia can be output that would enhance the resistance of the structure 220 to bending, shear and torsional stresses. Successful application of the structural enhancements can be performed by different 3D printing technologies under the guidance of the cooperative robotic network 240.

The cooperative robotic network 240 can include swarm robots 242 that are automated or semi-automated units deployed to facilitate the additive manufacturing process. The swarm robots 242 work collaboratively, following the instructions set by a computational algorithm determined by the system 100, to accurately deposit 3D printed material, e.g., to form the feature 230 and ribs 232, to maintain the stability of the printing process, and redistribute any increased load resulting from the addition of material to ensure overall structural balance and safety. The cooperative robotic network 240 also records the outcomes of the modifications, feeding this data back to the system 100 for continuous learning and improvement of the system. The system 100 can communicate with the cooperative robotic network 240 wirelessly or through other communication methods or protocols.

The swarm robots 242 can include a print head and a filament payload that can be selectively applied to form the modifications. Structural support can be applied to carry the load 206 during the repair process. Structural support can include beams, columns, or other structures.

The swarm robots 242 provide an additive manufacturing method by which modifications are physically made. The swarm robots 242 calculate optimal positioning needed for applying the 3D print material. The swarm robots 242 work together to establish the necessary support and foundation for the printing process, factoring in gravity and potential disturbances during printing.

Equipped with the necessary tools for material deposition from the 3D printing software component 112 (FIG. 1), the swarm robots 242 can execute printing permissions, putting material in place as per received instructions. Utilizing a layer-by-layer deposition process, the additive manufacturing method strategically adds material to specified areas of the structure 220 to enhance resistance to deflection without excessively increasing the structure's self-weight. The cooperative robotic network 240 facilitates the additive manufacturing method by getting the swarm robots 242 to work collaboratively, following the instructions set by a computational algorithm, to accurately deposit the 3D printed material, maintain the stability of the printing process, and redistribute any increased load resulting from the addition of material to ensure overall structural balance and safety.

The cooperative robotic network 240 receives and analyses an input from the 3D printing software component 112. The data includes specific details about where modifications are needed, the type, and the extent of modification. The cooperative robotic network 240 can also record the outcomes of the modifications, feeding this data back to the system 100 for continuous learning and improvement of the system 100.

During and/or after 3D printing, the system 100 employs feedback from the sensors 104 to ensure strengthening goals were achieved and if further tuning is needed. While the 3D printing is in process, the swarm robots 242 continuously monitor to ensure that the addition of material does not adversely affect the structure 220. The swarm robots 242 apply real-time adjustments to the structure 220 to safely redistribute an incurred load increase across the structure 220. Once the 3D printing is complete, post-processing steps like support removal, surface finishing, and thermal treatments may be needed. Subsequently, a quality assurance check is run to check that the printed modifications align accurately with the design specifications from the computational analysis component 108 (FIG. 1). Any discrepancies would loop back to the computational analysis component 108 for reevaluation and subsequent adjustments, for a continuous cycle of improvement.

Once the printing and reinforcement process is complete, sensory feedback is collected and shared back with the system 100 to confirm the success of the applied modifications. Historic load and performance data of the existing structure 220 can be employed for training a machine learning model, e.g., LSTM 115 (FIG. 1).

The LSTM 115 can simulate various load patterns and predict potential weak points iteratively. The LSTM 115 can be trained on historical structural loads and performance data until the prediction accuracy crosses a defined threshold. The system 100 can employ other types of machine learning neural networks as well to assist in determining information useful in evaluating the data, design techniques, the design parameters, etc., needed to provide loading patterns, understand changes to moments of inertia, etc.

The neural network(s), which can include the LSTM 115, can provide a system that improves functioning and accuracy through exposure to additional empirical data. The neural network (or networks) becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the input data belongs to each of the classes can be output.

The empirical data, also known as training data, from a set of examples can be formatted as a string of values and fed into the input of the neural network. Each example may be associated with a known result or output. Examples can include 3D print outcomes associated with a set of structural parameters, etc. Each example can be represented as a pair, (x, y), where x represents the input data and y represents the known output. The input data may include a variety of different data types and may include multiple distinct values. The neural network can have one input node for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, a trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. An exemplary simple neural network has an input layer of source nodes, and a single computation layer having one or more computation nodes that also act as output nodes, where there is a single computation node for each possible category into which the input example could be classified. An input layer can have a number of source nodes equal to the number of data values in the input data. The data values in the input data can be represented as a column vector. Each computation node in the computation layer generates a linear combination of weighted values from the input data fed into nodes of the input layer and applies a non-linear activation function that is differentiable to the sum. The exemplary simple neural network can perform classification on linearly separable examples (e.g., patterns).

A deep neural network, such as a multilayer perceptron, can have an input layer of source nodes, one or more computation layer(s) having one or more computation nodes, and an output layer, where there is a single output node for each possible category into which the input example could be classified. An input layer can have a number of source nodes equal to the number of data values in the input data. The computation nodes in the computation layer(s) can also be referred to as hidden layers because they are between the source nodes and output node(s) and are not directly observed. Each node in a computation layer generates a linear combination of weighted values from the values output from the nodes in a previous layer and applies a non-linear activation function that is differentiable over the range of the linear combination. The weights applied to the value from each previous node can be denoted, for example, by w₁, w₂, . . . w_{n-1,} wₙ. The output layer provides the overall response of the network to the input data. A deep neural network can be fully connected, where each node in a computational layer is connected to all other nodes in the previous layer, or may have other configurations of connections between layers. If links between nodes are missing, the network is referred to as partially connected.

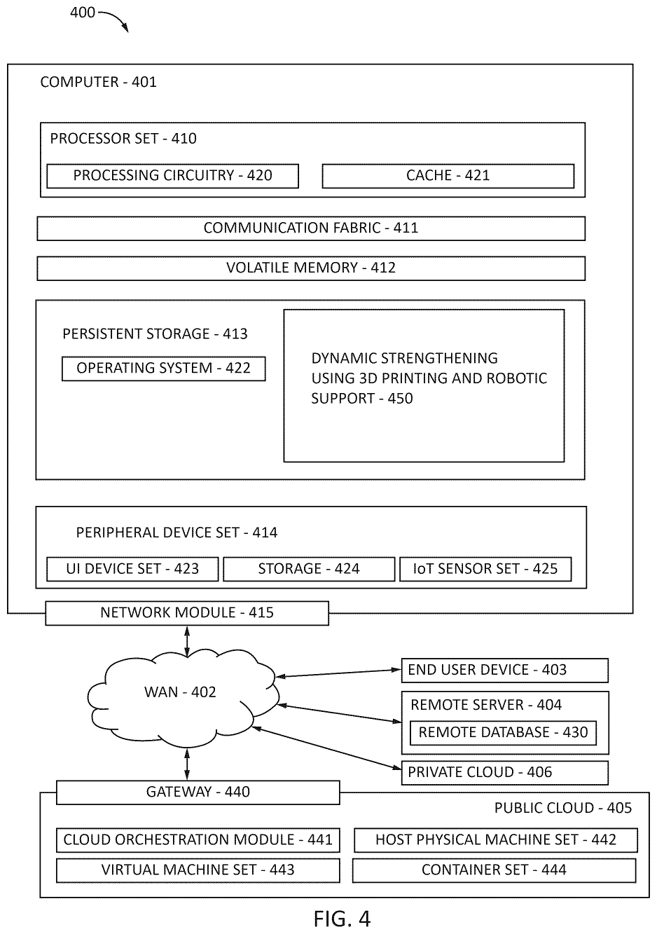

Referring to FIG. 4, a computing environment 400 contains an example of an environment for the execution of at least some of the computer code involved in performing the inventive methods, such as dynamic strengthening using 3D printing and robotic support 450. In addition to block 450, computing environment 400 includes, for example, computer 401, wide area network (WAN) 402, end user device (EUD) 403, remote server 404, public cloud 405, and private cloud 406. In this embodiment, computer 401 includes processor set 410 (including processing circuitry 420 and cache 421), communication fabric 411, volatile memory 412, persistent storage 413 (including operating system 422 and block 450, as identified above), peripheral device set 414 (including user interface (UI) device set 423, storage 424, and Internet of Things (IoT) sensor set 425), and network component 415. Remote server 404 includes remote database 430. Public cloud 405 includes gateway 440, cloud orchestration component 441, host physical machine set 442, virtual machine set 443, and container set 444.

COMPUTER 401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 430. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically computer 401, to keep the presentation as simple as possible. Computer 401 may be located in a cloud, even though it is not shown in a cloud in FIG. 4. On the other hand, computer 401 is not required to be in a cloud except to any extent as may be affirmatively indicated.

PROCESSOR SET 410 includes one, or more, computer processors of any type now known or to be developed in the future. Processing circuitry 420 may be distributed over multiple packages, for example, multiple, coordinated integrated circuit chips. Processing circuitry 420 may implement multiple processor threads and/or multiple processor cores. Cache 421 is memory that is located in the processor chip package(s) and is typically used for data or code that should be available for rapid access by the threads or cores running on processor set 410. Cache memories are typically organized into multiple levels depending upon relative proximity to the processing circuitry. Alternatively, some, or all, of the cache for the processor set may be located “off chip.” In some computing environments, processor set 410 may be designed for working with qubits and performing quantum computing.

Computer readable program instructions are typically loaded onto computer 401 to cause a series of operational steps to be performed by processor set 410 of computer 401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 421 and the other storage media discussed below. The program instructions, and associated data, are accessed by processor set 410 to control and direct performance of the inventive methods. In computing environment 400, at least some of the instructions for performing the inventive methods may be stored in block 450 in persistent storage 413.

COMMUNICATION FABRIC 411 is the signal conduction path that allows the various components of computer 401 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 412 is any type of volatile memory now known or to be developed in the future. Examples include dynamic type random access memory (RAM) or static type RAM. Typically, volatile memory 412 is characterized by random access, but this is not required unless affirmatively indicated. In computer 401, the volatile memory 412 is located in a single package and is internal to computer 401, but, alternatively or additionally, the volatile memory may be distributed over multiple packages and/or located externally with respect to computer 401.

PERSISTENT STORAGE 413 is any form of non-volatile storage for computers that is now known or to be developed in the future. The non-volatility of this storage means that the stored data is maintained regardless of whether power is being supplied to computer 401 and/or directly to persistent storage 413. Persistent storage 413 may be a read only memory (ROM), but typically at least a portion of the persistent storage allows writing of data, deletion of data and re-writing of data. Some familiar forms of persistent storage include magnetic disks and solid state storage devices. Operating system 422 may take several forms, such as various known proprietary operating systems or open source Portable Operating System Interface-type operating systems that employ a kernel. The code included in block 450 typically includes at least some of the computer code involved in performing the inventive methods.

PERIPHERAL DEVICE SET 414 includes the set of peripheral devices of computer 401. Data communication connections between the peripheral devices and the other components of computer 401 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 423 may include components such as a display screen, speaker, microphone, wearable devices (such as goggles and smart watches), keyboard, mouse, printer, touchpad, game controllers, and haptic devices. Storage 424 is external storage, such as an external hard drive, or insertable storage, such as an SD card. Storage 424 may be persistent and/or volatile. In some embodiments, storage 424 may take the form of a quantum computing storage device for storing data in the form of qubits. In embodiments where computer 401 is required to have a large amount of storage (for example, where computer 401 locally stores and manages a large database) then this storage may be provided by peripheral storage devices designed for storing very large amounts of data, such as a storage area network (SAN) that is shared by multiple, geographically distributed computers. IoT sensor set 425 is made up of sensors that can be used in Internet of Things applications. For example, one sensor may be a thermometer and another sensor may be a motion detector.

NETWORK COMPONENT 415 is the collection of computer software, hardware, and firmware that allows computer 401 to communicate with other computers through WAN 402. Network component 415 may include hardware, such as modems or Wi-Fi signal transceivers, software for packetizing and/or de-packetizing data for communication network transmission, and/or web browser software for communicating data over the internet. In some embodiments, network control functions and network forwarding functions of network component 415 are performed on the same physical hardware device. In other embodiments (for example, embodiments that utilize software-defined networking (SDN)), the control functions and the forwarding functions of network component 415 are performed on physically separate devices, such that the control functions manage several different network hardware devices. Computer readable program instructions for performing the inventive methods can typically be downloaded to computer 401 from an external computer or external storage device through a network adapter card or network interface included in network component 415. WAN 402 is any wide area network (for example, the internet) capable of communicating computer data over non-local distances by any technology for communicating computer data, now known or to be developed in the future. In some embodiments, the WAN 402 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 403 is any computer system that is used and controlled by an end user (for example, a customer of an enterprise that operates computer 401), and may take any of the forms discussed above in connection with computer 401. EUD 403 typically receives helpful and useful data from the operations of computer 401. For example, in a hypothetical case where computer 401 is designed to provide a recommendation to an end user, this recommendation would typically be communicated from network component 415 of computer 401 through WAN 402 to EUD 403. In this way, EUD 403 can display, or otherwise present, the recommendation to an end user. In some embodiments, EUD 403 may be a client device, such as thin client, heavy client, mainframe computer, desktop computer and so on.

REMOTE SERVER 404 is any computer system that serves at least some data and/or functionality to computer 401. Remote server 404 may be controlled and used by the same entity that operates computer 401. Remote server 404 represents the machine(s) that collect and store helpful and useful data for use by other computers, such as computer 401. For example, in a hypothetical case where computer 401 is designed and programmed to provide a recommendation based on historical data, then this historical data may be provided to computer 401 from remote database 430 of remote server 404.

PUBLIC CLOUD 405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 405 is performed by the computer hardware and/or software of cloud orchestration component 441. The computing resources provided by public cloud 405 are typically implemented by virtual computing environments that run on various computers making up the computers of host physical machine set 442, which is the universe of physical computers in and/or available to public cloud 405. The virtual computing environments (VCEs) typically take the form of virtual machines from virtual machine set 443 and/or containers from container set 444. It is understood that these VCEs may be stored as images and may be transferred among and between the various physical machine hosts, either as images or after instantiation of the VCE. Cloud orchestration component 441 manages the transfer and storage of images, deploys new instantiations of VCEs and manages active instantiations of VCE deployments. Gateway 440 is the collection of computer software, hardware, and firmware that allows public cloud 405 to communicate through WAN 402. Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 406 is similar to public cloud 405, except that the computing resources are only available for use by a single enterprise. While private cloud 406 is depicted as being in communication with WAN 402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 405 and private cloud 406 are both part of a larger hybrid cloud.

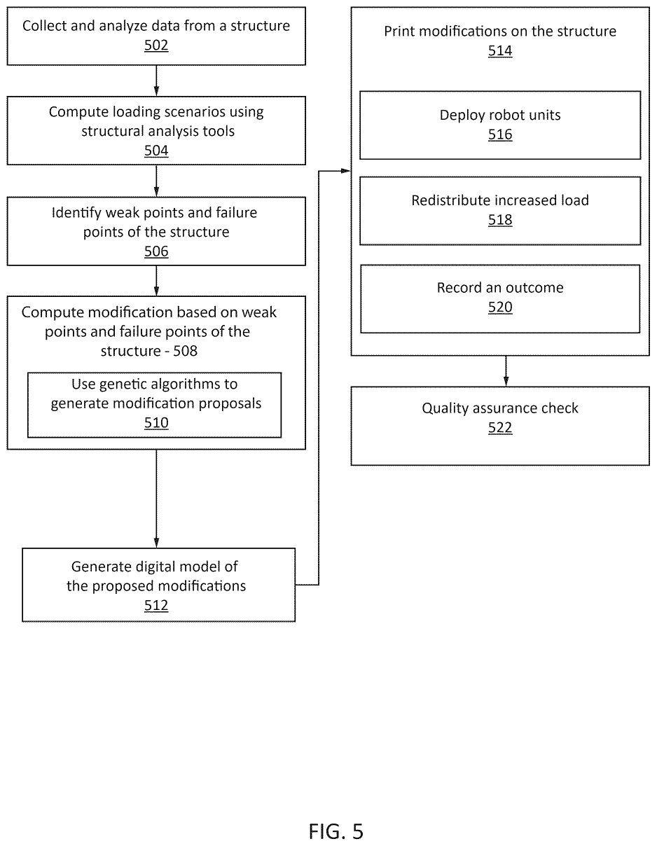

Referring to FIG. 5, a system/computer-implemented method for dynamic strengthening using 3D printing and robotic support in accordance with embodiments of the present invention is shown and described. In block 502, data relating to physical attributes of a structure and load distribution patterns is collected and analyzed. The data can be collected from sensors, IoT sensors, physical measurements or specification information (engineering drawings, etc.) for the structure. In block 504, loading scenarios on the structure can be computed and/or simulated based on one or more structural analysis tools. The structural analysis tools can include machine leaning techniques, FEA or other software tools. The machine learning technique can include an LSTM network to simulate various load patterns and predict potential weak points.

In block 506, weak points and failure points are identified based on the simulation. In block 508, modifications to the structure are computed based on the weak points and failure points. This can include adding material in a digital model to adjust the moment of inertia of the structure, among other things. In block 510, genetic algorithms can be employed to generate and test various cross-sectional modification proposals.

In block 512, a digital model of the modifications to the structure is generated. In block 514, the modifications to the structure are 3D printed by adding material to the weak points and failure points on the structure utilizing a layer-by-layer deposition process. In block 516, the material added to the weak points and failure points can include deploying robotic units to collaboratively add the material to the weak points and failure points. The robotic units can include swarm robots. In block 518, the robotic units can redistribute any increased load resulting from the added materials. In block 520, the robotic units can record an outcome of the modifications, where the recordings are fed back to the system for continuous learning.

In block 522, a quality assurance check can be performed after adding material to verify that printed modifications align with design specifications from a computational analysis.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor-or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a component, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer-implemented method, comprising:
analyzing collected data relating to physical attributes of a structure and load distribution patterns;
simulating loading scenarios on the structure based on one or more structural analysis tools;
identifying weak points and failure points based on simulation;
computing modifications to the structure based on the weak points and failure points;
generating a digital model of the modifications to the structure; and
three-dimensional (3D) printing the modifications to the structure by adding material to the weak points and failure points on the structure utilizing a layer-by-layer deposition process.

2. The computer-implemented method of claim 1, wherein adding the material to the weak points and failure points further comprises:
deploying robotic units to collaboratively add the material to the weak points and failure points; and
redistributing any increased load resulting from added materials.

3. The computer-implemented method of claim 2, further comprising:
recording an outcome of the modifications, wherein recordings are fed back for continuous learning.

4. The computer-implemented method of claim 1, wherein the one or more structural analysis tools includes a machine learning technique, wherein the machine learning technique includes a Long Short-Term Memory (LSTM) network to simulate various load patterns and predict potential weak points.

5. The computer-implemented method of claim 1, wherein computing modifications to the structure further comprises:
using genetic algorithms to generate and test various cross-sectional modification proposals.

6. The computer-implemented method of claim 1, wherein analyzing collected data further comprises:
collecting data from embedded Internet of Things (IoT) sensors in the structure.

7. The computer-implemented method of claim 1, further comprising:
performing a quality assurance check after adding material to verify that printed modifications align with design specifications from a computational analysis.

8. A system, comprising:
a processor set;
one or more computer-readable storage media; and
program instructions stored on the one or more computer-readable storage media to cause the processor set to perform operations comprising:
analyzing collected data relating to physical attributes of a structure and load distribution patterns;
simulating loading scenarios on the structure based on one or more structural analysis tools;
identifying weak points and failure points based on simulation;
computing modifications to the structure based on the weak points and failure points;
generating a digital model of the modifications to the structure; and
three-dimensional (3D) printing the modifications to the structure by adding material to the weak points and failure points on the structure utilizing a layer-by-layer deposition process.

9. The system of claim 8, wherein adding the material to the weak points and failure points further comprises:
deploying robotic units to collaboratively add the material to the weak points and failure points; and
redistributing any increased load resulting from added materials.

10. The system of claim 9, further comprising:
recording an outcome of the modifications, wherein recordings are fed back for continuous learning.

11. The system of claim 8, wherein the one or more structural analysis tools includes a machine learning technique, wherein the machine learning technique includes a Long Short-Term Memory (LSTM) network to simulate various load patterns and predict potential weak points.

12. The system of claim 8, wherein computing modifications to the structure further comprises:
using genetic algorithms to generate and test various cross-sectional modification proposals.

13. The system of claim 8, wherein analyzing collected data further comprises:
collecting data from embedded Internet of Things (IoT) sensors in the structure.

14. The system of claim 8, wherein the operations further comprise:
performing a quality assurance check after adding material to verify that printed modifications align with design specifications from a computational analysis.

15. A computer program product, comprising:
one or more computer-readable storage media; and
program instructions stored on the one or more computer-readable storage media to perform operations comprising:
analyzing collected data relating to physical attributes of a structure and load distribution patterns;
simulating loading scenarios on the structure based on one or more structural analysis tools;
identifying weak points and failure points based on simulation;
computing modifications to the structure based on the weak points and failure points;
generating a digital model of the modifications to the structure; and
controlling three-dimensional (3D) printing the modifications to the structure by adding material to the weak points and failure points on the structure utilizing a layer-by-layer deposition process.

16. The computer program product of claim 15, wherein adding the material to the weak points and failure points further comprises:
deploying robotic units to collaboratively add the material to the weak points and failure points; and
redistributing any increased load resulting from added materials.

17. The computer program product of claim 16, further comprising:
recording an outcome of the modifications, wherein recordings are fed back for continuous learning.

18. The computer program product of claim 15, wherein the one or more structural analysis tools includes a machine learning technique, wherein the machine learning technique includes a Long Short-Term Memory (LSTM) network to simulate various load patterns and predict potential weak points.

19. The computer program product of claim 15, wherein computing modifications to the structure further comprises:
using genetic algorithms to generate and test various cross-sectional modification proposals.

20. The computer program product of claim 15, wherein the operations further comprise:
performing a quality assurance check after adding material to verify that printed modifications align with design specifications from a computational analysis.
